(19) United States
(12) Patent Application Publication
(10) Pub. No.: US 2008/0217659 A1
(43) Pub. Date: Sep. 11, 2008

(54) Device and Method To Reduce Cross-Talk and Blooming For Image Sensors

(75) Inventors: Jyh-Ming Hung, Changhua County (TW); Dun-Nian Yaung, Taipei City (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/682,401

(22) Filed: Mar. 6, 2007

(51) Int. Cl. H01L 27/148; H01L 21/00

(52) U.S. Cl. 257/223; 438/79; 257/E27.162; 257/E21.001

(57) ABSTRACT

An image sensor device includes a semiconductor substrate having a first type of conductivity, a first layer overlying the semiconductor substrate and having the first type of conductivity, a second layer overlying the first layer and having a second type of conductivity different than the first type of conductivity, and a plurality of pixels formed in the second layer.

### CROSS REFERENCE

The present disclosure is related to the commonly-assigned U.S. Patent Application, Serial No. (Attorney Docket Number TSMC 2006-0708), filed (unknown), entitled “CROSS-TALK REDUCTION THROUGH DEEP PIXEL WELL IMPLANT FOR IMAGE SENSORS,” the entire disclosure of which is hereby incorporated herein by reference.

### BACKGROUND

In semiconductor technologies, image sensors are used for sensing a volume of exposed light projected towards the semiconductor substrate. Complementary metal-oxide-semiconductor (CMOS) image sensors (CIS) and charged-coupled device (CCD) sensors are widely used in various applications such as digital still camera applications. These devices utilize an array of pixels or image sensor elements, including photodiodes and transistors, to collect photo energy to convert images into electrical signals.

However, image sensors may suffer from cross-talk and/or blooming. That is, light targeted for one image sensor element (and the electrical signal generated thereby) may spread to other neighboring image sensor elements. In some cases, a blaze of light (high intensity) may generate an overflow of electrons that may spread to other image sensor elements. This will degrade spatial resolution, reduce overall optical sensitivity, and result in poor color separation.

Therefore, what is needed is a simple and cost-effective device and method to reduce cross-talk and blooming in image sensors.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a top view of an image sensor including a plurality of pixels, according to one or more embodiments of the present disclosure.

FIG. 2 is a cross-sectional view of a conventional image sensor device that suffers from cross-talk and blooming.

FIG. 3 is a cross-sectional view of an image sensor device including a deep well implant.

FIG. 4 is a cross-sectional view of an image sensor device according to one embodiment of the present disclosure.

FIG. 5 is a flow chart of a method for fabricating the image sensor of FIG. 4 according to one embodiment of the present disclosure.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

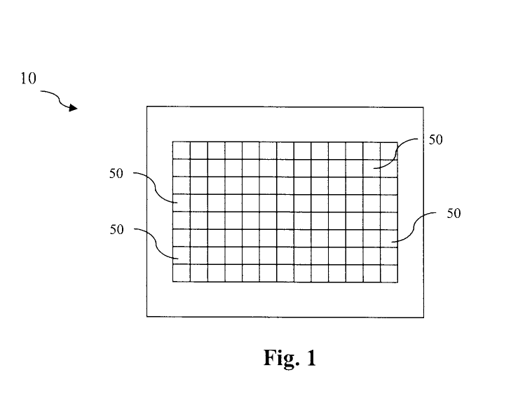

Referring now to FIG. 1, illustrated is a top view of an image sensor 10 including a grid or array of pixels 50 (sometimes referred to as image sensor elements). Additional circuitry and input/outputs are typically provided adjacent to the grid of pixels 50 for providing an operation environment for the pixels and for supporting external communications with the pixels. The image sensor 10 may include a charge-coupled device (CCD) sensor, complimentary metal oxide semiconductor (CMOS) image sensor (CIS), an active-pixel sensor, and a passive-pixel sensor. Additionally, the image sensor 10 may be a front-side or back-side illuminated sensor.

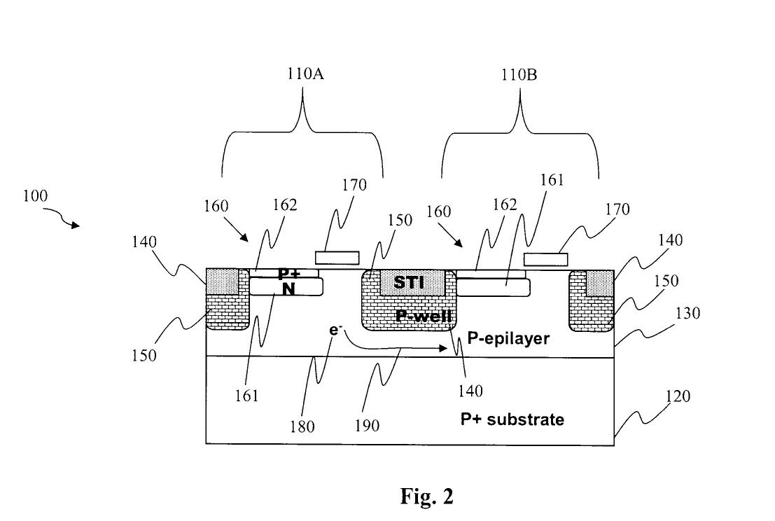

Referring now to FIG. 2, illustrated is a cross-sectional view of a conventional image sensor 100 that suffers from cross-talk and/or blooming. The image sensor 100 is shown with two unit pixels 110A, 110B for clarity and simplicity. The image sensor 100 may comprise a semiconductor substrate 120. The substrate 120 may include a silicon substrate in a crystalline structure. In the present example, the substrate 120 is a heavily doped P-type silicon substrate. The image sensor 100 further comprises a lightly doped P-type epilayer 130 formed on the P-type silicon substrate 120. The image sensor 100 further comprises a shallow trench isolation (STI) feature 140 for isolating the pixels 110A, 110B and a guard-ring P-type well (P-well) 150 substantially underlying the STI feature.

The pixels 110A, 110B may each include a photodiode 160 for sensing an amount of light radiation. The photodiode 160 may comprise of an N-type doped region 161 formed in the P-type epilayer 130 and a heavily doped P-type region 162 (also referred to as P-type pinned layer) formed on the surface of the N-type doped region 161. Accordingly, the P-N-P junction region makes up the light sensing region of the photodiode 160. The pixels 110A, 110B may further include a transfer gate transistor having a gate electrode 170 formed on the P-type epilayer 130. It is understood that the transfer gate transistor may include other features such as a source and drain region which are not illustrated for the sake of clarity.

During operation, incident light may be directed towards the pixels 110A, 110B and may reach the photodiode 160. The light that reaches the photodiode 160 may generate optical charges or photo-electrons (e⁻) 180 that are collected and accumulated in the light sensing region. The photo-electrons may be transferred via the transfer transistor and may be converted into a digital signal. The amount of photo-electrons generated is proportional to the intensity of the light (e.g., number of photons that are absorbed in the light sensing region). However, since the pixels 110A, 110B are narrowly spaced from each other, some of the photo-electrons 180 generated by longer wavelengths of light may spread 190 into adjacent pixels through the epilayer 130 which causes cross-talk. Additionally, the photodiode 160 may have a maximum number of photo-electrons that it can collect and accumulate in the light sensing region. Thus, a blaze of light (very high intensity) may generate an overflow or surplus of photo-electrons 180 that may spread 190 into adjacent pixels through the epilayer 130 which causes blooming. As the pixel pitch and scaling continues to shrink with emerging technologies, cross-talk and/or blooming issues will become exacerbated.

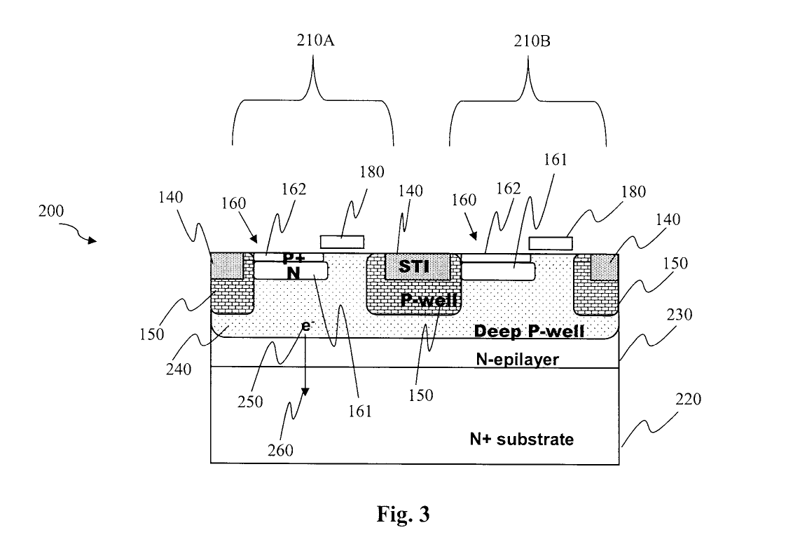

Referring now to FIG. 3, illustrated is cross-sectional view of an image sensor 200 including pixels having a deep P-type well on an N-type epilayer and heavily doped N-type substrate configuration. Similar features in FIGS. 2 and 3 are numbered the same for simplicity and clarity. Even though only two unit pixels 210A, 210B are shown, it is understood that the image sensor 200 may include many millions of pixels. The image sensor 200 may comprise a semiconductor substrate 220. The semiconductor substrate 220 may be a heavily doped N-type substrate (N+ substrate). The image sensor 200 may further comprise a lightly doped N-type epilayer (N-epilayer) 230 formed on the substrate 220. A deep P-type well (deep P-well) 240 may be formed on the epilayer 230. The deep P-well 240 may be formed by ion implantation with an implanter using a P-type dopant, such as boron. The implanter may provide very good control of the dopant concentration and ion penetration depth. The depth of the deep P-well 240 may depend on the energy value of the implanter such that the higher the implanter energy the deeper the ion penetration depth. The pixels 210A, 210B may be the same type as the pixels 110A, 110B described in FIG. 2.

During operation, photo-electrons (e⁻) may be generated by light radiation that is absorbed in the light-sensing region (P-N-P junction region) of the photodiode 160. As previously discussed, some of the photo-electrons 250 generated in one pixel 210A may spread into an adjacent pixel 210B. However, the N-epilayer may be configured to collect these photo-electrons 250 and provide an overflow path 260 so that the photo-electrons are prevented from spreading into other pixels. Additionally, the N+ substrate may be electrically biased so that the photo-electrons 250 collected in the N-epilayer may be attracted to flow out of the substrate. In this way, cross-talk and/or blooming between the plurality of pixels 210A, 210B is greatly reduced. One of the disadvantages of utilizing pixels with the deep P-well configuration is that high energy may be required to form the deep well. There may be energy limitations with the implanter in some applications. Furthermore, the high energy may cause damage to the semiconductor substrate during ion implantation.

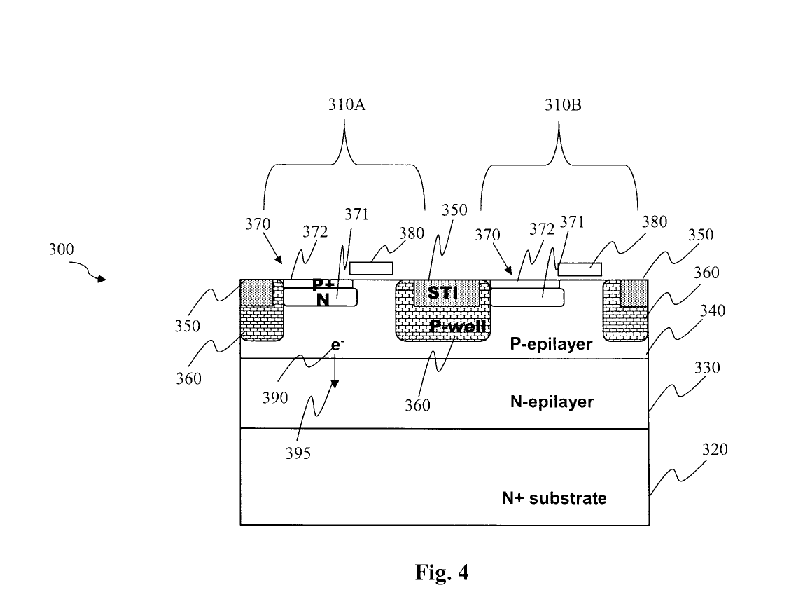

Referring now to FIG. 4, illustrated is a cross-sectional view of an image sensor 300 that is configured to reduce cross-talk and/or blooming according to the present disclosure. Even though only two unit pixels 310A, 320A are shown, it is understood that the image sensor 300 may include many millions of pixels. The images sensor 300 may comprise a semiconductor substrate 320. The semiconductor substrate 320 includes a silicon having a crystalline structure. The substrate 320 may also include other elementary semiconductors such as germanium. Alternatively, the substrate 320 may optionally include a compound semiconductor such as silicon carbide, gallium arsenic, indium arsenide, and indium phosphide. In the present embodiment, the substrate 320 may include silicon having a first type of conductivity such as an N-type silicon. The N-type silicon may be formed by heavily doping the silicon with an N-type dopant, such as phosphorous, arsenic, or other suitable material. The doping may be implemented by an ion implantation or a diffusion process known in the art.

The image sensor 300 may further comprise a first epilayer 330 formed on the heavily doped N-type substrate (N+ substrate) 320 and having the first type of conductivity. The first epilayer 330 may include an N-type epilayer (N-epilayer) formed by an epitaxial growth process. The N-epilayer may be configured to have a lower concentration of the N-type dopant, such as phosphorous or arsenic, than the N+ substrate 320.

The image sensor 300 may further comprise a second epilayer 340 formed on the first epilayer 330. The second epilayer 340 may have a second type of conductivity different from the first type of conductivity. In the present embodiment, the second epilyaer 340 may include a P-type epilayer (P-epilayer) formed by an epitaxial growth process. The P-epilayer may be configured to include a low concentration of P-type dopant, such as boron, BF₂, or other suitable material. Additionally, the thickness of the second epilayer 340 may depend on the configuration of the pixels 310A, 310B, the out-diffusion range of the N-epilayer, and the ion implantation depth of the guard-ring wells (described below). Furthermore, the second epilayer 340 may be configured to have a thickness that ranges from 2.5 μm to 4.0 μm so that current techniques and processes may be implemented to form the pixels 310A, 310B.

The image sensor 300 may further comprise a plurality of isolation features 350 such as shallow trench isolation (STI) features for isolating the pixels 310A, 310B from each other. The isolation features 350 may also isolate other active regions (not shown) in the second epilayer 340 used for forming various devices such as transistors. The isolation features 350 may be formed in the second epilayer 340 by a suitable process known in the art. The isolation features 350 may be filled with a dielectric material and may further include an oxide layer lining the side walls of the isolation features.

The images sensor 300 may further comprise a plurality of guard-ring wells 360 substantially underlying the isolation features 350. Since the second epilayer 340 in the present embodiment is a P-epilayer, the guard-ring wells 360 may be doped with a P-type dopant, such as boron or other suitable material, to form a guard-ring P-type well (P-well). The guard-ring wells 360 may be formed by an ion implantation using an implanter. The depth of the guard-ring wells 360 may depend on the energy value of the implanter. Additionally, the depth and dopant concentration of the guard-ring wells 360 may be configured to reduce the diffusion of generated photo-electrons from one pixel 310A to another pixel 310B.

The pixels 310A, 310B may each include a photodiode 370 formed in the second epilayer 340 for sensing an amount of light radiation. In the present embodiment, the photodiode 370 is an N-type photodiode. The photodiode 370 may comprise an N-type doped region 371 formed in the P-epilayer. The photodiode 370 may further comprise a P-type pinned layer 372 formed over the surface of the N-type doped region 371. Accordingly, the P-N-P junction region may make up the light sensing region of the photodiode 370. The pixels 310A, 310B may further include a transfer gate transistor having a gate electrode 380 formed on the P-epilayer. It is understood that the transfer gate transistor may include other features such as a source and drain region which are not illustrated for the sake of simplicity and clarity. Even though the present embodiment discloses a photodiode and a transfer gate transistor, it is understood that other microelectronic elements may be implemented for the pixels. Other microelectronic elements include, but are not limited, to a pinned layer photodiode, photogate, photo transistor, reset gate transistor, source follower transistor, row select transistor, and combinations thereof.

The image sensor 300 may further comprise a plurality of interconnect metal layers overlying the second epilayer 340 for providing connections between the various microelectronic elements formed on the substrate 320. The interconnect metal layers may include conductive materials such as aluminum, aluminum/silicon/copper alloy, titanium, titanium nitride, tungsten, polysilicon, metal silicide, or combinations thereof. The interconnects may be formed by a process including physical vapor deposition (or sputtering), chemical vapor deposition (CVD), or other suitable technique. Alternatively, the interconnect metal layers may include copper, copper alloy, titanium, titanium nitride, tantalum, tantalum nitride, tungsten, polysilicon, metal silicide, or combinations thereof.

The interconnect metal layers may be disposed and insulated in an interlayer dielectric. The interlayer dielectric may include a material of a low dielectric constant such as a dielectric constant less than about 3.5. The interlayer dielectric may include silicon dioxide, silicon nitride, silicon oxynitride, polyimide, spin-on glass (SOG), fluoride-doped silicate glass (FSG), carbon doped silicon oxide, Black Diamond® (Applied Materials of Santa Clara, Calif.), Xerogel, Aerogel, amorphous fluorinated carbon, Parylene, SiLK (Dow Chemical, Midland, Michigan), polyimide, and/or other suitable materials. The interlayer dielectric may be formed by a technique including spin-on, CVD, or sputtering. Additionally, the interconnect metal layer and interlayer dielectric may be formed in an integrated process such as a damascene process or lithography/plasma etching process.

The image sensor 300 may further comprise a color filter and a microlens (not shown) formed on the substrate 320. During operation, the color filter and microlens are configured to filter through a desired type of light radiation (e.g., red, green, blue light) and direct it towards the light sensing region (P-N-P junction region) of the photodiode 370. The light radiation that is absorbed in the light sensing region may generate optical charges or photo-electrons (e⁻) 390 which may be collected and accumulated by the photodiode 370. The amount of photo-electrons 390 generated may be proportional to the intensity of the light radiation. These photo-electrons 390 may be transferred via the transfer gate transistor and may then be converted to a digital signal by other microelectronic elements formed on the substrate 320.

In some circumstances, the photo-electrons 390 generated in one pixel 310A may spread into an adjacent pixel 310B through the second epilayer 340 which causes cross-talk and/or blooming. The photo-electrons 390 may be generated by longer wavelengths of light which are absorbed deeper in the photodiode 370. Additionally, an overflow or surplus of photo-electrons 390 may be generated by a blaze of light (high intensity) which exceeds the full well capacity of the photodiode 370. However, the first epilayer 330 being an N-epilayer may provide a collection region (e.g., P-N junction region of P-epilayer and N-epilayer) for the photo-electrons 390 that are generated by longer wavelengths of light, thereby greatly reducing cross-talk. Additionally, the N-epilayer may also provide a bypass path 395 for the overflow or surplus photo-electrons 390, thereby greatly reducing blooming. Since the substrate 320 includes a N+ substrate, an ohmic contact with very low resistance can easily be formed so that the photo-electrons 390 can flow from the N-epilayer and out of the substrate. Furthermore, the N-epilayer and/or the N+ substrate may configured to be electrically biased to attract the electrons moving towards the substrate 320 and prevent the electrons from diffusing into neighboring pixels. In the present embodiment, the image sensor 300 does not have a deep well configuration for the pixels and thus, the implanter energy limitation may be avoided as well as the damage caused by the high energy during ion implantation.

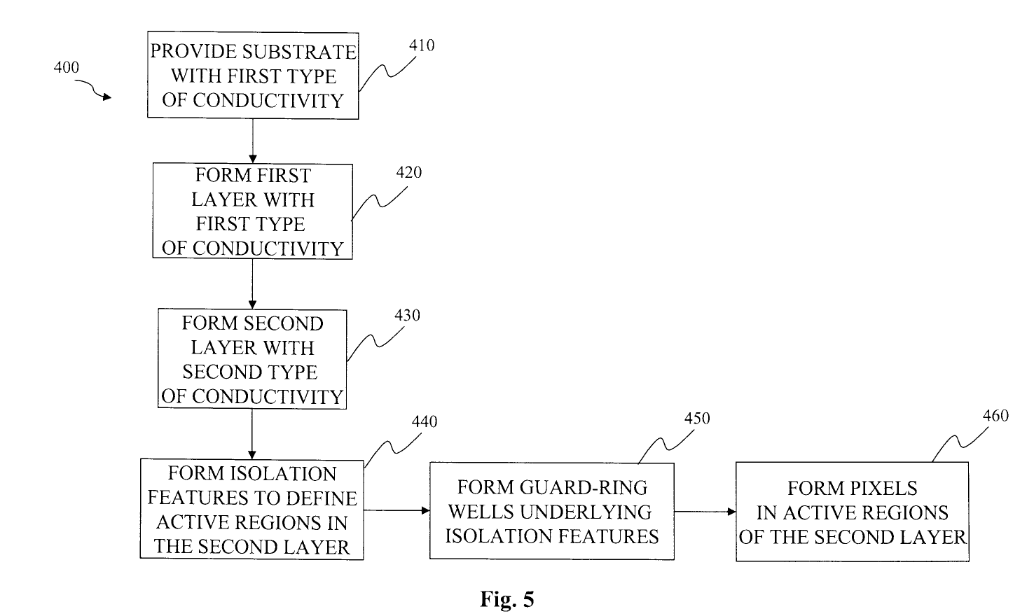

Referring now to FIG. 5, illustrated is a flow chart of a method 400 of making the image sensor 300 of FIG. 4. The method 400 begins with step 410 in which a substrate is provided having a first type of conductivity. The substrate may include a heavily doped N-type silicon substrate (N+ substrate). The doping may be performed by ion implantation or diffusion. The N+ substrate may be configured to be electrically biased during operation. The method 400 continues with step 420 in which a first layer may be formed on the substrate having the first type of conductivity. The first layer may include an N-type epilayer (N-epilayer) formed by an epitaxial growth process. The first layer may have a lower concentration of an N-type dopant, such as phosphorous or arsenic, than the substrate. The N-epilayer may be configured to be electrically biased during operation. The method 400 continues with step 430 in which a second layer may be formed on the first layer having a second type of conductivity different than the first type of conductivity. The second layer may include a P-type epilayer (P-epilayer) formed by an epitaxial growth process. The second layer may have a low concentration of a P-type dopant, such as boron or BF₂.

The method 400 continues with step 440 in which a plurality of isolation features such as shallow trench isolation (STI) features may be formed to define and isolate a plurality of active regions in the second layer. The STI features may be formed by techniques and processes known in the art. The method 400 continues with step 450 in which a plurality of guard-ring wells may be formed having the second type of conductivity. The guard-ring wells may include guard-ring P-type wells (P-wells) that substantially underlie each of the STI features.

The method 400 continues with step 460 in which a plurality of pixels may be formed in the active regions of the second layer. Since the second layer includes a lightly doped P-epilayer, the plurality of pixels may be performed by current pixel fabrication techniques and processes. For example, the plurality of pixels may be configured to include a photodiode, pinned layer photodiode, photogate, photo transistor, transfer gate transistor, reset gate transistor, source follower transistor, row select transistor, and combinations thereof.

In the disclosed image sensors and the method to make the same, the light radiation that may be received during operation may not be limited to visual light (e.g., red, green, blue light), but can be extended to other types of light radiation such as infrared (IR) and ultraviolet (UV) light. Accordingly, the pixels and various other devices may be properly designed and configured for effectively reflecting and/or absorbing the corresponding light radiation beam.

Thus, the present disclosure provides an image sensor device. The image sensor device includes a semiconductor substrate having a first type of conductivity, a first layer overlying the semiconductor substrate and having the first type of conductivity, a second layer overlying the first layer and having a second type of conductivity different from the first type of conductivity, and a plurality of pixels formed in the second layer. In some embodiments, the plurality of pixels include microelectronic elements selected from a group consisting of: a photodiode, pinned layer photodiode, photogate, photo transistor, transfer gate transistor, reset gate transistor, source follower transistor, row select transistor, and combinations thereof. In other embodiments, the semiconductor substrate includes a semiconductor substrate that is heavily doped with a dopant of the first type of conductivity. The semiconductor substrate is configured and operable to provide an ohmic contact during operation. In some embodiments, the first layer includes an epilayer that is light doped with the dopant of the first type of conductivity. In other embodiments, the first layer is configured and operable to be electrically biased during operation.

In some embodiments, the second layer includes an epilayer that is lightly doped with a dopant of the second type of conductivity. In other embodiments, the image sensor device further includes a plurality of shallow trench isolation (STI) features and a plurality of guard-ring wells having the second type of conductivity. Each STI feature is disposed between the plurality of pixels. Each guard ring substantially underlies each STI feature. In other embodiments, the thickness of the second layer is larger than the depth of the guard-ring wells. In still other embodiments, the second layer has a thickness ranging from about 2.5 μm to 4.0 μm.

In another embodiment, the present disclosure provides a method for fabricating an image sensor. The method includes providing a semiconductor substrate having a first type of conductivity, forming a first layer overlying the semiconductor substrate and having the first type of conductivity, forming a second layer overlying the first layer and having a second type of conductivity, and forming a plurality of pixels in the second layer. In some embodiments, the forming the first layer includes epitaxially growing an epilayer that is lightly doped with a dopant of the first type of conductivity. In other embodiments, the forming the second layer includes epitaxially growing an epilayer that is light doped with a dopant of the second type of conductivity.

In still other embodiments, the method further comprises electrically biasing the first layer to prevent cross-talk. In other embodiments, the forming the plurality of pixels includes forming microelectronic elements selected from a group consisting of: a photodiode, pinned layer photodiode, photogate, photo transistor, transfer gate transistor, reset gate transistor, source follower transistor, row select transistor, and combinations thereof. In other embodiments, the method further comprises forming a plurality of shallow trench isolation (STI) features and forming a plurality of guard-ring wells. Each STI feature is disposed between the plurality of pixels. Each guard ring substantially underlies each STI feature.

The present disclosure also provides a semiconductor device including a substrate having a first type of dopant, a first layer formed on the substrate and having the first type of dopant, a second layer formed on the first layer and having a second type of dopant different from the first type of dopant, and a plurality of image sensor elements formed in the second layer. In some embodiments, the semiconductor device includes a plurality of shallow trench isolation (STI) features for isolating each of the plurality of sensor elements and a plurality of wells having the second type of dopant substantially underlying each of the plurality of STI features. In some embodiments, the substrate is heavily doped with the first type of dopant. The first layer is lightly doped with the first type dopant. The second layer is lightly doped with the second type of dopant. In still other embodiments, each of the plurality of image sensor elements includes a photodiode and at least one transistor.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. It is understood that various different combinations of the above listed processing steps can be used in combination or in parallel. Also, features illustrated and discussed in some embodiments can be combined with features illustrated and discussed above with respect to other embodiments. Those skilled in the art should also realize that such equivalent constructions do not depart from the spirit and scope of the present disclosure, and that they may make various changes, substitutions and alterations herein without departing from the spirit and scope of the present disclosure. For example, various features and the doping configurations disclosed herein may be reversed accordingly for proper functionality.

Several different advantages exist from these and other embodiments. In addition to providing an efficient and cost-effective device and method for reducing cross-talk and blooming in image sensors, the device and method disclosed herein can easily be fabricated and integrated with current semiconductor processing equipment and techniques. The limitations of processing equipment and techniques can be avoided by implementing the device and method disclosed herein. Therefore, the device and method disclosed herein may be used effectively and successfully even as pixel scaling continues to shrink with emerging technologies.

What is claimed is:

1. An image sensor device, comprising:
a semiconductor substrate having a first type of conductivity;
a first layer overlying the semiconductor substrate and having the first type of conductivity;
a second layer overlying the first layer and having a second type of conductivity different from the first type of conductivity; and
a plurality of pixels formed in the second layer.

2. The device of claim 1, wherein the plurality of pixels include microelectronic elements selected from a group consisting of: a photodiode, pinned layer photodiode, photogate, photo transistor, transfer gate transistor, reset gate transistor, source follower transistor, row select transistor, and combinations thereof.

3. The device of claim 1, wherein the semiconductor substrate includes a semiconductor substrate that is heavily doped with a dopant of the first type of conductivity.

4. The device of claim 3, wherein the semiconductor substrate is configured and operable to provide an ohmic contact during operation.

5. The device of claim 3, wherein the first layer includes an epilayer that is lightly doped with the dopant of the first type of conductivity.

6. The device of claim 5, wherein the first layer is configured and operable to be electrically biased during operation.

7. The device of claim 5, wherein the second layer includes an epilayer that is lightly doped with a dopant of the second type of conductivity.

8. The device of claim 1, further comprising:
a plurality of shallow trench isolation (STI) features, wherein each of the plurality of STI features is disposed between the plurality of pixels; and
a plurality of guard-ring wells having the second type of conductivity, wherein each of the plurality of guard-ring wells substantially underlies each of the plurality of STI features.

9. The device of claim 8, wherein the thickness of the second layer is larger than the depth of the plurality of guard-ring wells.

10. The device of claim 8, wherein the thickness of the second layer ranges from about 2.5 μm to 4 μm.

11. A method for fabricating an image sensor, comprising:
providing a semiconductor substrate having a first type of conductivity;
forming a first layer overlying the semiconductor substrate and having the first type of conductivity;
forming a second layer overlying the first layer and having a second type of conductivity different from the first type of conductivity; and
forming a plurality of pixels in the second layer.

12. The method of claim 11, wherein the forming the first layer includes epitaxially growing an epilayer that is lightly doped with a dopant of the first type of conductivity.

13. The method of claim 12, wherein the forming the second layer includes epitaxially growing an epilayer that is lightly doped with a dopant of the second type of conductivity.

14. The method of claim 12, further comprising electrically biasing the first layer to prevent cross-talk.

15. The method of claim 11, wherein the forming the plurality of pixels includes forming microelectronic elements selected from a group consisting of: a photodiode, pinned layer photodiode, photogate, photo transistor, transfer gate transistor, reset gate transistor, source follower transistor, row select transistor, and combinations thereof.

16. The method of claim 11, further comprising:
forming a plurality of shallow trench isolation (STI) features, wherein each of the plurality of STI features is disposed between the plurality of pixels; and
forming a plurality of guard-ring wells having the second type of conductivity, wherein each of the plurality of guard-ring wells substantially underlies each of the plurality of STI features.

17. A semiconductor device, comprising:
a substrate having a first type of dopant;
a first layer formed on the substrate and having the first type of dopant;
a second layer formed on the first layer and having a second type of dopant different form the first type of dopant; and
a plurality of image sensor elements formed in the second layer.

18. The device of claim 17, further comprising:
a plurality of shallow trench isolation (STI) features for isolating each of the plurality of sensor elements; and
a plurality of wells having the second type of dopant substantially underlying each of the plurality of STI features.

19. The device of claim 18, wherein the substrate is heavily doped with the first type of dopant, wherein the first layer is lightly doped with the first type of dopant, and wherein the second layer is lightly doped with the second type of dopant.

20. The device of claim 19, wherein each of the plurality of image sensor elements includes a photodiode and at least one transistor.
